(19) United States
(12) Patent Application Publication
(10) Pub. No.: US 2026/0052887 A1
(43) Pub. Date: Feb. 19, 2026

(54) Organic Light-Emitting Diode Display with Optical Cavities

(71) Applicant: Apple Inc., Cupertino, CA (US)

(72) Inventors: Roohollah Samadzadeh Tarighat, San Mateo, CA (US); Anatole Huang, Campbell, CA (US); Andrew Lin, San Jose, CA (US); Arghavan Arjmand, Santa Clara, CA (US); Chang Ming Lu, New Taipei (TW); Chao Liang Chien, Hsinchu (TW); Cheuk Chi Lo, Belmont, CA (US); Chi-Jui Chung, Palo Alto, CA (US); Chin-Wei Kang, Baoshan Township (TW); Ching-Sang Chuang, Sunnyvale, CA (US); Fu-Yu Teng, Taoyuan (TW); Jui-Chih Liao, Hsinchu City (TW); Michael Slootsky, Santa Clara, CA (US); Sheng Hui Shen, Hsinchu (TW); Steven E Molesa, San Jose, CA (US); Takahide Kuranaga, Machida (JP); Wookyung Bae, San Jose, CA (US); Yu-Wen Liu, Hsinchu City (TW); Yuan-Yu Lin, Taoyuan (TW)

(21) Appl. No.: 19/272,314

(22) Filed: Jul. 17, 2025

Related U.S. Application Data
(60) Provisional application No. 63/683,158, filed on Aug. 14, 2024.

(51) Int. Cl. H10K 59/80

(52) U.S. Cl. CPC H10K 59/876; H10K 59/80517; H10K 59/80518

(57) ABSTRACT

Pixels in an organic light-emitting diode (OLED) display may be microcavity OLED pixels having optical cavities. The optical cavities may be defined by a partially transparent cathode layer and a reflective anode structure. The anode of the pixels may include both the reflective anode structure and one or more transparent anode structures that are used to tune the thickness of the optical cavity for each pixel. Organic light-emitting diode layers may be formed over the pixels and may have a uniform thickness in each pixel in the display. The display may include trenches in a substrate that create discontinuities in the reflective anode structures for the pixels. The anode stacks for the pixels may include one or more dielectric spacers with overhang portions.

This application claims the benefit of U.S. provisional patent application No. 63/683,158, filed Aug. 14, 2024, which is hereby incorporated by reference herein in its entirety.

### BACKGROUND

This relates generally to electronic devices, and, more particularly, to electronic devices with displays.

Electronic devices often include displays. For example, an electronic device may have an organic light-emitting diode (OLED) display based on organic light-emitting diode pixels. In this type of display, each pixel includes a light-emitting diode and transistors for controlling application of a signal to the light-emitting diode to produce light. The light-emitting diodes may include OLED layers positioned between an anode and a cathode. To emit light from a given pixel in an organic light-emitting diode display, a voltage may be applied to the anode and the cathode of the given pixel.

Some OLED pixels may include microcavity OLED pixels, where OLED layers are covered by a partially transparent layer to form an optical cavity. The thickness of the optical cavity may be tuned so that light of a selected wavelength is emitted with high efficiency. However, if care is not taken, OLED pixels of this type may have non-uniform thicknesses, may have smaller than desired aperture ratios, may have lower than desired efficiency, and/or may require complex manufacturing processes.

It is within this context that the embodiments herein arise.

### SUMMARY

A display may include a plurality of pixels. The display may include a substrate, a reflective conductive layer with a first plurality of discrete portions on the substrate, a first transparent conductive layer with a second plurality of discrete portions, a second transparent conductive layer with a third plurality of discrete portions, and a dielectric spacer layer with a fourth plurality of discrete portions. Each one of a first subset of the plurality of pixels has a respective anode stack that comprises a respective one of the first plurality of discrete portions, a respective one of the second plurality of discrete portions, a respective one of the third plurality of discrete portions, and a respective one of the fourth plurality of discrete portions that is interposed between the respective one of the second plurality of discrete portions and the respective one of the third plurality of discrete portions.

A display may include a plurality of pixels. The display may include a substrate having a plurality of trenches, a layer that overlaps the substrate and that includes a plurality of overhang portions that overlap the plurality of trenches and define a plurality of undercuts, a reflective conductive layer with a first plurality of discrete portions on the layer and a second plurality of discrete portions in the plurality of trenches, and a transparent conductive layer with a third plurality of discrete portions on the reflective conductive layer. Each one of the plurality of pixels may include an anode stack that includes a respective one of the first plurality of discrete portions and a respective one of the third plurality of discrete portions.

A display may include a plurality of pixels. A pixel in the plurality of pixels may include a reflective anode portion, a transparent anode portion that is electrically connected to the reflective anode portion, organic light-emitting diode layers that overlap the transparent anode portion, the transparent anode portion being interposed between the reflective anode portion and the organic light-emitting diode layers, and a cathode that overlaps the organic light-emitting diode layers. The transparent anode portion may extend past an edge of the reflective anode portion to create an undercut under the transparent anode portion.

### BRIEF DESCRIPTION OF THE DRAWINGS

FIG. 1 is a schematic diagram of an illustrative electronic device having a display in accordance with some embodiments.

FIG. 2 is a schematic diagram of an illustrative display in accordance with some embodiments.

FIG. 3 is a diagram of an illustrative display pixel circuit in accordance with some embodiments.

FIG. 4 is a cross-sectional side view of an illustrative display having microcavity organic light-emitting diode pixels with vias in accordance with some embodiments.

FIG. 5 is a cross-sectional side view of an illustrative one-cavity display having microcavity organic light-emitting diode pixels and trenches between reflective anode structures in accordance with some embodiments.

FIG. 6 is a cross-sectional side view of an illustrative three-cavity display having microcavity organic light-emitting diode pixels and trenches between reflective anode structures in accordance with some embodiments.

FIG. 7 is a cross-sectional side view of an illustrative two-cavity display having microcavity organic light-emitting diode pixels, transparent anode structures formed from different materials, and trenches between reflective anode structures in accordance with some embodiments.

FIG. 8 is a cross-sectional side view of an illustrative two-cavity display having microcavity organic light-emitting diode pixels, a dielectric spacer layer, and trenches between reflective anode structures in accordance with some embodiments.

FIG. 9 is a cross-sectional side view of an illustrative two-cavity display having microcavity organic light-emitting diode pixels, a dielectric spacer layer, a conductive contact between transparent anode structures, and trenches between reflective anode structures in accordance with some embodiments.

FIG. 10 is cross-sectional side view of an illustrative two-cavity display having microcavity organic light-emitting diode pixels, a dielectric spacer with an overhang portion, and a polyimide pixel definition layer between anode stacks in accordance with some embodiments.

FIG. 11 is cross-sectional side view of an illustrative two-cavity display having microcavity organic light-emitting diode pixels, a dielectric spacer with an overhang portion, and a polyimide plug under the overhang portion in accordance with some embodiments.

FIG. 12 is cross-sectional side view of an illustrative three-cavity display having microcavity organic light-emitting diode pixels, a dielectric spacer with an overhang portion, and a polyimide plug under the overhang portion in accordance with some embodiments.

FIG. 13 is cross-sectional side view of an illustrative two-cavity display having microcavity organic light-emitting diode pixels and multiple transparent anode structures in accordance with some embodiments.

FIG. 14 is cross-sectional side view of an illustrative three-cavity display having microcavity organic light-emitting diode pixels and transparent anode structures of varying thicknesses in accordance with some embodiments.

FIG. 15 is cross-sectional side view of an illustrative three-cavity display having microcavity organic light-emitting diode pixels, transparent anode structures of varying thicknesses, and polyimide plugs in accordance with some embodiments.

FIG. 16 is cross-sectional side view of an illustrative three-cavity display having microcavity organic light-emitting diode pixels, transparent anode structures of varying thicknesses, and a planarized via in accordance with some embodiments.

FIG. 17 is cross-sectional side view of an illustrative three-cavity display having microcavity organic light-emitting diode pixels and dielectric spacer layers of varying thicknesses in accordance with some embodiments.

FIG. 18 is cross-sectional side view of an illustrative two-cavity display having microcavity organic light-emitting diode pixels and dielectric spacer layers of varying thicknesses in accordance with some embodiments.

### DETAILED DESCRIPTION

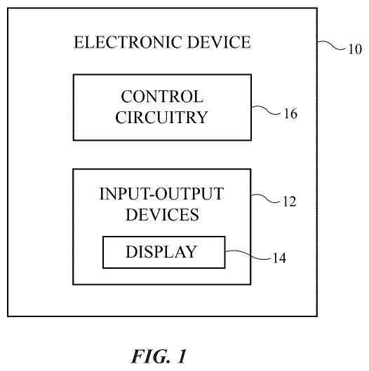

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

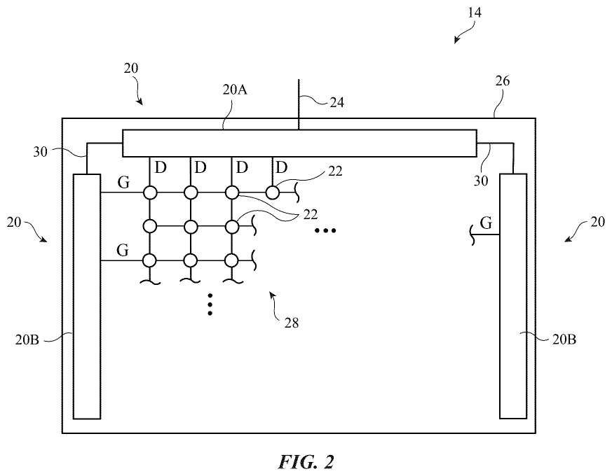

FIG. 2 is a diagram of an illustrative display 14. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, silicon layers, composite films that include polymer and inorganic materials, metallic foils, etc.

Display 14 may have an array of pixels 22 for displaying images for a user such as pixel array 28. Pixels 22 in array 28 may be arranged in rows and columns. The edges of array 28 may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Display 14 may include pixels 22 of different colors. As an example, display 14 may include red pixels, green pixels, and blue pixels. Pixels of other colors such as cyan, magenta, and yellow might also be used.

Display driver circuitry 20 may be used to control the operation of pixels 28. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 as shown in FIG. 2.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D while issuing control signals to supporting display driver circuitry such as gate driver circuitry 20B over signal paths 30. With the illustrative arrangement of FIG. 2, data lines D run vertically through display 14 and are associated with respective columns of pixels 22.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally across display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.).

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel 22 may have a light-emitting diode and circuitry (e.g., circuitry on substrate 26) that responds to the control and data signals from display driver circuitry 20.

Gate driver circuitry 20B may include blocks of gate driver circuitry such as gate driver row blocks. Each gate driver row block may include circuitry such output buffers and other output driver circuitry, register circuits (e.g., registers that can be chained together to form a shift register), and signal lines, power lines, and other interconnects. Each gate driver row block may supply one or more gate signals to one or more respective gate lines in a corresponding row of the pixels of the array of pixels in the active area of display 14.

A schematic diagram of an illustrative pixel circuit of the type that may be used for each pixel 22 in array 28 is shown in FIG. 3. As shown in FIG. 3, display pixel 22 may include light-emitting diode 38. A positive power supply voltage ELVDD may be supplied to positive power supply terminal 34 and a ground power supply voltage ELVSS may be supplied to ground power supply terminal 36. Diode 38 has an anode (terminal AN) and a cathode (terminal CD). The state of drive transistor 32 controls the amount of current flowing through diode 38 and therefore the amount of emitted light 40 from display pixel 22. Cathode CD of diode 38 is coupled to ground terminal 36, so cathode terminal CD of diode 38 may sometimes be referred to as the ground terminal for diode 38.

To ensure that transistor 32 is held in a desired state between successive frames of data, display pixel 22 may include a storage capacitor such as storage capacitor Cst. The voltage on storage capacitor Cst is applied to the gate of transistor 32 at node A to control transistor 32. Data can be loaded into storage capacitor Cst using one or more switching transistors such as switching transistor 33. When switching transistor 33 is off, data line D is isolated from storage capacitor Cst and the gate voltage on terminal A is equal to the data value stored in storage capacitor Cst (i.e., the data value from the previous frame of display data being displayed on display 14). When gate line G (sometimes referred to as a scan line) in the row associated with display pixel 22 is asserted, switching transistor 33 will be turned on and a new data signal on data line D will be loaded into storage capacitor Cst. The new signal on capacitor Cst is applied to the gate of transistor 32 at node A, thereby adjusting the state of transistor 32 and adjusting the corresponding amount of light 40 that is emitted by light-emitting diode 38. If desired, the circuitry for controlling the operation of light-emitting diodes for display pixels in display 14 (e.g., transistors, capacitors, etc. in display pixel circuits such as the display pixel circuit of FIG. 3) may be formed using other configurations (e.g., configurations that include circuitry for compensating for threshold voltage variations in drive transistor 32, etc.). The display pixel may include additional switching transistors, emission transistors in series with the drive transistor, etc. Capacitor Cst may be positioned at other desired locations within the pixel (e.g., between the source and gate of the drive transistor). The display pixel circuit of FIG. 3 is merely illustrative.

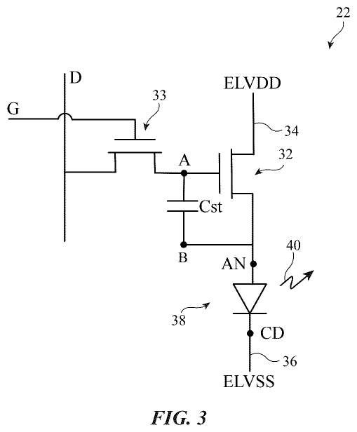

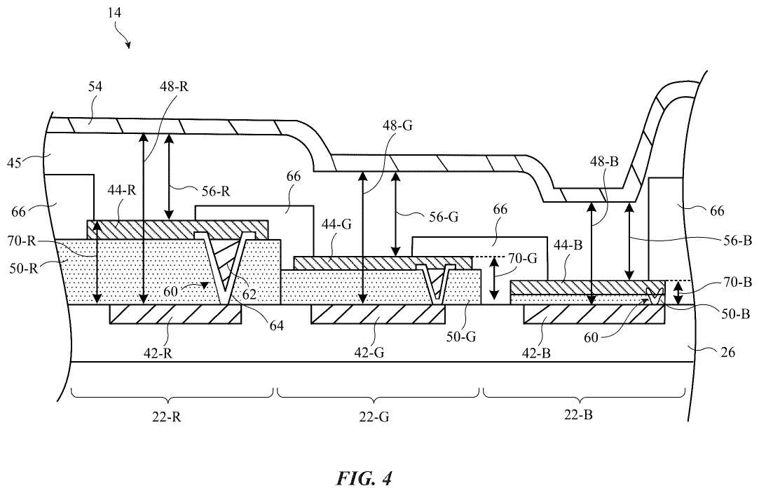

FIG. 4 is a cross-sectional side view of an illustrative display with organic light-emitting diode display pixels. As shown, display 14 may include a substrate 26. Substrate 26 may be formed from glass, plastic, polymer, silicon, or any other desired material. Substrate 26 may include transistor circuitry for applying control signals to the pixels. The transistor circuitry may include bulk transistors (where transistors are formed on the surface of a semiconductor substrate such as a silicon substrate). Another option is for the transistor circuitry to include thin-film transistors (TFTs), where a thin semiconductor film layer (e.g., formed from poly-crystalline or amorphous silicon) is formed on an insulating substrate (e.g., a glass or plastic substrate). In general, the OLED pixels described herein may include any desired combination of thin-film transistors and bulk transistors. FIG. 4 shows a red pixel 22-R, a blue pixel 22-B, and a green pixel 22-G.

Anodes 42 such as anodes 42-R, 42-G, and 42-B may be formed on substrate 26.

Anodes 42-R, 42-G, and 42-B may be formed from conductive material and may be covered by OLED layers 45 and cathode 54. OLED layers 45 may include one or more layers for forming an organic light-emitting diode. For example, layers 45 may include one or more of a hole-injection layer (HIL), a hole-transport layer (HTL), an electron-block layer (EBL), an emissive layer (EML), an electron-transport layer (ETL), an electronic-injection layer (EIL), and a charge generation layer (CGL). OLED layers 45 may form a plurality of single diodes or a plurality of tandem diodes. OLED layers 45 may be formed from white OLED layers (e.g., OLED layers configured to emit white light), combinations of red, green, blue, and/or yellow OLED layers, etc. Cathode 54 may be a conductive layer formed on the OLED layers 45. Cathode layer 54 may form a common cathode terminal (see, e.g., cathode terminal CD of FIG. 3) for all diodes in display 14. Each anode in display 14 may be independently controlled, so that each diode in display 14 can be independently controlled. This allows each pixel 22 to produce an independently controlled amount of light.

In some OLED displays, cathode 54 is entirely (or almost entirely) transparent and anodes 42 may be in direct contact with OLED layers 45. The display of FIG. 4, however, uses an optical cavity to enhance efficiency and color purity in the display. Using optical cavities as in FIG. 4 allows for uniform white OLED layers 45 to provide red, green, and blue light from red pixel 22-R, green pixel 22-G, and blue pixel 22-B respectively. An optical cavity may be formed by reflective layers within the display that are formed on either side of the OLED layers. By tuning the thickness of the optical cavity that includes the OLED layers, each pixel may be optimized to have high emission at a desired wavelength. To form an optical cavity of this type, display 14 in FIG. 4 includes a partially transparent cathode layer 54 and additional anode portions 44.

Cathode layer 54 may be formed from a partially transparent conductive material. In one illustrative example, cathode layer 54 may be formed from a combination of magnesium (Mg) and silver (Ag). Cathode layer 54 may be formed form any other desired conductive material or combination of conductive materials. Cathode 54 may transmit less than 90% of light, may transmit less than 80% of light, may transmit less than 70% of light, may transmit less than 60% of light, may transmit less than 50% of light, may transmit more than 40% of light, may transmit more than 50% of light, may transmit more than 60% of light, may transmit between 40% and 80% of light, may transmit between 45% and 60% of light, may transmit between 60% and 70% of light, may transmit between 50% and 75% of light, etc. Cathode 54 may reflect more than 10% of light, may reflect more than 20% of light, may reflect more than 30% of light, may reflect more than 40% of light, may reflect more than 50% of light, may reflect more than 60% of light, may reflect less than 50% of light, may reflect less than 60% of light, may reflect between 20% and 60% of light, may reflect between 40% and 55% of light, may reflect between 30% and 40% of light, may reflect between 25% and 50% of light, etc.

Cathode layer 54 may define a first boundary for the optical cavity. The other boundary of the optical cavity may be set by anode 42 (sometimes referred to as anode portion 42, reflective anode portion 42, reflective anode structure 42, etc.). Anodes 42-R, 42-G, and 42-B may be formed from a highly reflective material such as an aluminum copper (AlCu) alloy, a silver alloy (a combination of silver and at least one other material such as copper, germanium, palladium, etc.), or any other desired conductive material. Each anode 42 may reflect more than 70% of light (e.g., visible light), more than 80% of light, more than 90% of light, more than 95% of light, more than 99% of light, etc.

Additional layers may be formed over anodes 42 between the anodes and OLED layers 45. However, these additional layers may be transparent and therefore do not disrupt the optical cavity. Because the additional layers are transparent, the boundaries of the optical cavity are still determined by the reflective anode 42 and cathode 54. The presence of the additional transparent layers between anode 42 and cathode 54 may result in an increased distance between the reflective anode 42 and cathode 54 (because the OLED thickness is uniform). FIG. 4 shows how pixel 22-R has an optical cavity with thickness 48-R between anode 42-R and cathode 54. Pixel 22-G has an optical cavity with thickness 48-G between anode 42-G and cathode 54. Pixel 22-B has an optical cavity with thickness 48-B between anode 42-B and cathode 54.

Each optical cavity thickness is tuned to optimize emission of the desired color of light for that pixel. For a given optical cavity thickness, light of a given wavelength will resonate due to multiple reflections off of the walls (e.g., cathode 54 and anode 42) of the optical cavity. The increased emission at the given wavelength caused by resonance within the optical cavity may be referred to as a microcavity effect. Pixels that are optimized to induce this effect (such as the pixels in FIG. 4) may be referred to as microcavity OLED pixels.

Pixel 22-R has an optical cavity thickness 48-R that maximizes emission of red light. Pixel 22-G has an optical cavity thickness 48-G that maximizes emission of green light. Pixel 22-B has an optical cavity thickness 48-B that maximizes emission of blue light. Blue light has a shorter wavelength than green light, which has a shorter wavelength than red light. Generally, the thickness of the optical cavity may be proportional to the wavelength of the type of light that is intended to be emitted. Therefore, thickness 48-B is less than thickness 48-G and thickness 48-G is less than thickness 48-R. This example is merely illustrative and does not necessarily hold true for all display designs, as other factors such as the node of the cavity may influence the optical cavity.

The thickness of each optical cavity is therefore tuned to optimize emission of light. However, changing the thickness of each optical cavity may present difficulties during manufacturing. To reduce complexity and cost in manufacturing microcavity OLED displays, additional anode portions 44 may be included in each pixel. As shown in FIG. 4, red pixel 22-R has an additional anode portion 44-R, green pixel 22-G has an additional anode portion 44-G, and blue pixel 22-B has an additional anode portion 44-B. These additional anode portions 44 (sometimes referred to as supplementary anodes 44, anodes 44, transparent anodes 44, transparent anode structures 44, etc.) may be formed from a transparent conductive material. The additional anode portions may be formed from a transparent conductive oxide such as indium tin oxide (ITO), indium zinc oxide (IZO), or any other desired transparent conductive material. Because the additional anodes are transparent, they may be used to tune the optical cavity thickness 48 of the pixels without disrupting the optical cavity between reflective anode 42 and cathode 54.

A pixel definition layer 66 may be formed between each pixel. The pixel definition layer may be formed from a non-conducting material and may be interposed between adjacent anodes of the display. The pixel definition layer may be formed from a non-conductive material (that is either opaque or transparent) and may have openings in which the anodes are formed, thereby defining the area of each pixel.

One or more additional layers may be included between anode portion 44 and anode portion 42 in each pixel. As shown in FIG. 4, dielectric spacers 50 (sometimes referred to as spacers, dielectric layers, etc.) are included in display 14. A first dielectric spacer 50-R is formed over anode 42-R in red pixel 22-R. A second dielectric spacer 50-G is formed over anode 42-G in green pixel 22-G. A third dielectric spacer 50-B is formed over anode 42-B in blue pixel 22-B. It should be noted that multiple dielectric layers may be used to make up each one of dielectric spacers 50. In some cases, a single dielectric layer may be shared between multiple dielectric spacers. For example, a first dielectric layer may form a portion of spacer 50-R and the entirety of spacer 50-G. In this case, spacer 50-R may include a second dielectric layer to increase the thickness of the overall spacer 50-R relative to spacer 50-G.

Dielectric spacers 50 as well as supplemental anodes 44 may all be transparent or substantially transparent. This allows the layers to serve as spacers that can have thicknesses chosen to tune the thickness of the optical cavity for each pixel. Dielectric spacers 50 as well as supplemental anodes 44 may transmit more than 90% of incident light, more than 95% of incident light, more than 99% of incident light, more than 99.9% of incident light, etc. Dielectric spacers 50 may be formed from one or more layers of silicon dioxide, silicon oxynitride, another desired oxide material, silicon nitride, or any other desired transparent material.

Dielectric spacers 50 serve as spacer structures that allow tuning of cavity thickness 48 for each pixel. For case of manufacturing, it is desirable for a uniform thickness white OLED layer 45 to be formed over each supplemental anode 44. This way, OLED layers 45 may be formed in a single deposition step instead of being patterned to have different thicknesses and/or different color OLED material for each pixel. As shown in FIG. 4, the OLED thickness 56-R of pixel 22-R, the OLED thickness 56-G of pixel 22-G, and the OLED thickness 56-B of pixel 22-B are approximately (e.g., within 5% of) the same.

Without dielectric spacers 50 and supplemental anodes 44, having a uniform thickness OLED layer would result in the optical cavity thickness of each pixel being the same. Including dielectric spacers and supplemental anodes as in FIG. 4 allows for the optical cavity thickness to be tuned for a desired color.

Supplemental anodes 44 may be electrically connected to anodes 42. As shown in FIG. 4, a via 60 may be formed that extends through dielectric spacer 50-R to electrically connect anode portion 44-R to anode portion 42-R. In FIG. 4, via 60 includes a filler portion 62 (that may be conductive or non-conductive) and a conductive liner 64. Another via having the same structure (e.g., with a conductive portion and a conductive liner) is also formed through dielectric spacer 50-G to electrically connect supplemental anode 44-G to anode 42-G. Another via having the same structure (e.g., with a conductive portion and a conductive liner) is also formed through dielectric spacer 50-B to electrically connect supplemental anode 44-B to anode 42-B.

Each layer in display 14 may have any desired thickness. In some arrangements, supplemental anode portions 44-R, 44-G, and 44-B may have the same thickness (e.g., within 5%, within 3%, within 1%, etc.). Each supplemental anode portion may have a thickness of less than 100 nanometers, less than 50 nanometers, less than 30 nanometers, less than 20 nanometers, less than 15 nanometers, less than 10 nanometers, greater than 5 nanometers, between 5 and 50 nanometers, between 5 and 100 nanometers, etc. Similarly, each one of dielectric spacers 50 may have any desired thickness (e.g., less than 100 nanometers, less than 50 nanometers, less than 30 nanometers, less than 20 nanometers, less than 15 nanometers, less than 10 nanometers, greater than 5 nanometers, between 5 and 50 nanometers, between 5 and 100 nanometers, etc.).

The supplemental anode and underlying layers between the supplemental anode and anode may be referred to as an anode stack. For example, pixel 22-R has an anode stack that includes supplemental anode 44-R and dielectric spacer 50-R. The total thickness 70-R of the anode stack is tuned to determine the total optical cavity thickness 48-R. Pixel 22-G has an anode stack that includes supplemental anode 44-G and dielectric spacer 50-G. The total thickness 70-G of the anode stack is tuned to determine the total optical cavity thickness 48-G. Pixel 22-B has an anode stack that includes supplemental anode 44-B and dielectric spacer 50-B. The total thickness 70-B of the anode stack is tuned to determine the total optical cavity thickness 48-B. In one arrangement, the thickness 70-R of the anode stack of red pixel 22-R may be between 100 and 200 nanometers, the thickness 70-G of the anode stack of green pixel 22-G may be between 70 and 100 nanometers, and the thickness 70-B of the anode stack of blue pixel 22-B may be between 10 and 30 nanometers. These thickness values are merely illustrative. Each anode stack may have any desired thickness (e.g., greater than 200 nanometers, between 100 nanometers and 150 nanometers, between 50 and 125 nanometers, less than 100 nanometers, less than 50 nanometers, less than 25 nanometers, less than 20 nanometers, etc.). The reflective anode portion 42 may also sometimes be referred to as being part of the anode stack for a given pixel.

The example of FIG. 4 in which white OLED layers 45 are uniformly deposited for pixels 22-R, 22-G, and 22-B is merely illustrative. In some designs, each pixel may have corresponding OLED layers of that color. For example, red pixel 22-R may have red OLED layers (e.g., OLED layers that emit red light), green pixel 22-G may have green OLED layers (e.g., OLED layers that emit green light), and blue pixel 22-B may have blue OLED layers (e.g., OLED layers that emit blue light). This type of arrangement may offer efficiency improvements at the cost of increased manufacturing complexity.

Filler portion 62 of each via 60 may optionally be formed from the same material as supplemental anode portions 44. For example, if supplemental anode 44-R for pixel 22-R is formed from indium tin oxide, filler portion 62 of via 60 in pixel 22-R may also be formed from indium tin oxide. In some cases, conductive liner 64 may be included in the via 60 to prevent corrosion (caused by interaction between filler portion 62 and anode 42). Alternatively, if the via material is compatible with the anode material(s), conductive liner 64 may be omitted from the via and the via may include a single conductive material that is in direct contact with transparent anode structure 44 and reflective anode structure 42. Via 60 may include conductive materials such as titanium nitride, indium tin oxide, a combination of titanium nitride and indium tin oxide, etc.

In some cases, anodes 42 may be formed from an aluminum alloy such as aluminum copper (AlCu). However, a silver alloy may instead be used as the material for anodes 42. The silver alloy may have an increased reflectance relative to the aluminum copper.

To increase the aperture of the pixels in pixel array 28, it may be desirable to reduce the distance between adjacent anodes. Aperture ratio is the ratio of the light sensitive area of a pixel to the total area of that pixel. Mitigating anode-to-anode spacing may increase the aperture ratio of the pixels, which mitigates screen door effect.

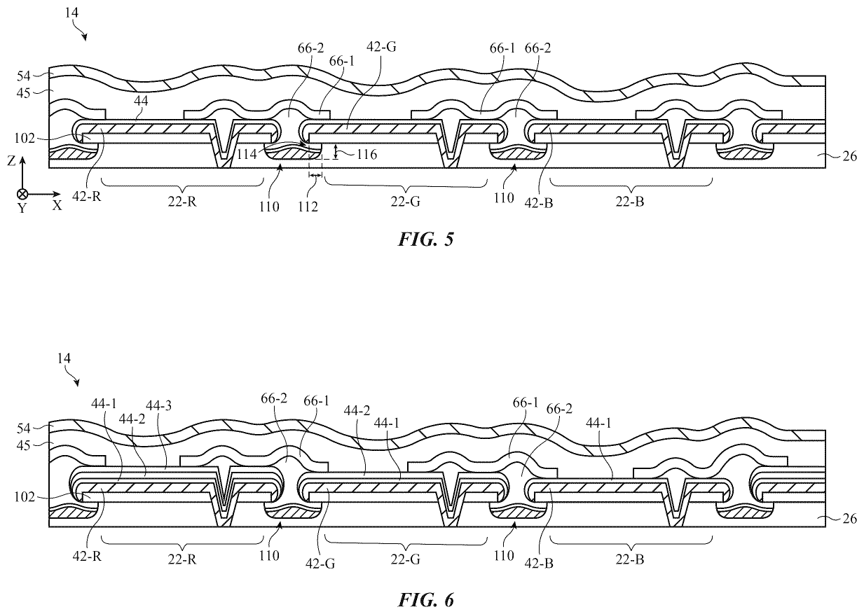

To mitigate anode-to-anode spacing for increased aperture ratio and resolution in pixel array 28, reflective anode portions 42 may be electrically isolated by trenches in an underlying substrate. The reflective anode portions of FIG. 4 may be formed using wet etching techniques. However, these types of wet etching techniques may have minimum anode-to-anode spacing requirements that are larger than desired. In the examples of FIGS. 5-9, trenches in substrate 26 are used to electrically isolate reflective anode portions for different pixels.

As shown in FIG. 5, substrate 26 has a plurality of trenches 110. Each trench 110 may be formed in substrate 26 between adjacent pixels 22 in the pixel array. The display also includes an overhang layer 102 that is interposed between the substrate 26 and the reflective anode portions 42. Overhang layer 102 may be formed from a dielectric material such as silicon dioxide, silicon nitride, silicon oxynitride, titanium oxide, aluminum oxide, etc. Overhang layer 102 may instead comprise a conductive material such as titanium, molybdenum, etc. In yet another possible arrangement, overhang layer 102 may be formed from polyimide and may be formed integrally with substrate 26. In other words, substrate 26 may be patterned to define the overhang portions and corresponding undercuts.

The majority of overhang layer 102 may be formed an upper surface of substrate 26 and is in direct contact with the upper surface of substrate 26. Overhang layer 102 may extend past substrate 26 in a direction parallel to the plane of display 14 (e.g., within the XY-plane of FIG. 5). As shown in FIG. 5, overhang layer has an edge that is separated from the edge of substrate 26 (and trench 110) by distance 112. This overhang region of overhang layer 102 defines an undercut 114. Distance 112 may be referred to as the width of undercut 114. Undercut 114 may have a height 116 defined by the separation between the lower surface of overhang layer 112 and the surface of substrate 26 that defines trench 110.

Each trench 110 therefore has two associated undercuts 114 defined by overhang layer 102 and sidewalls of the trench. Reflective anode portions 42-R, 42-G, and 42-B may be formed from a conductive layer 42. Each undercut 114 may create a discontinuity in conductive layer 42 during deposition of conductive layer 42 over the display during manufacturing of the display. The discontinuities in the reflective conductive layer 42 cause the conductive layer 42 to have discrete portions that are electrically isolated from one another. A first electrically isolated portion of conductive layer 42 forms reflective anode portion 42-R for a red pixel, a second electrically isolated portion of conductive layer 42 forms reflective anode portion 42-G for a green pixel, and a third electrically isolated portion of conductive layer 42 forms reflective anode portion 42-B for a blue pixel. There may also be a portion of conductive layer 42 formed in each trench 110, as shown in FIG. 5.

Each one of FIGS. 5-9 shows how trenches 110 may create electrically isolated reflective anode portions for pixels in display 14. Reflective anode portions formed using trenches in this manner may have a smaller anode-to-anode spacing compared to as in FIG. 4, thus increasing aperture ratio for the pixels.

In each one of FIGS. 5-9, uniform OLED layers 45 are formed over the red, blue, and green pixels in the pixel array. Cathode 54 is formed over the OLED layers. As discussed in connection with FIG. 4, the cavity thickness of each pixel may be selected to improve efficiency at a particular wavelength of light. Including different cavity thicknesses for each color pixel in the display may improve the efficiency of the display but may require additional manufacturing steps. Therefore, displays may sometimes have the same cavity thickness for all of the pixels in the pixel array (e.g., a one-cavity arrangement). Some displays may have two different cavity thicknesses for all of the pixels in the pixel array (e.g., a two-cavity arrangement). Some displays may have three different cavity thicknesses for all of the pixels in the pixel array (e.g., a three-cavity arrangement). When the display has three different cavity thicknesses, color filter elements may optionally be omitted from the display. When the display has one cavity thickness or two different cavity thicknesses, color filter elements may be included over some or all of the pixel colors in the pixel array of the display.

FIG. 5 shows an example of a one-cavity arrangement for display 14. As shown in FIG. 5, a transparent anode portion 44 of the same thickness is included in the red pixel 22-R, the blue pixel 22-B, and the green pixel 22-G. The cavity thickness of red pixel 22-R, blue pixel 22-B, and green pixel 22-G are therefore the same in FIG. 5. Red pixel 22-R may include a red color filter element, green pixel 22-G may include a green color filter element, and blue pixel 22-B may include a blue color filter element.

FIG. 6 shows an example of a three-cavity arrangement for display 14. As shown in FIG. 6, a first transparent conductive layer 44-1 is patterned to include a portion in red pixel 22-R, a portion in green pixel 22-G, and a portion in blue pixel 22-B. A second transparent conductive layer 44-2 is patterned to include a portion in red pixel 22-R, a portion in green pixel 22-G, but no portion in blue pixel 22-B. A third transparent conductive layer 44-3 is patterned to include a portion in red pixel 22-R but no portions in green pixel 22-G and blue pixel 22-B. With this arrangement, the red pixel 22-R has a transparent anode portion defined by layers 44-1, 44-2, and 44-3. The green pixel 22-G has a transparent anode portion defined by layers 44-1 and 44-2. The blue pixel 22-B has a transparent anode portion defined by layer 44-1. The red pixel 22-R therefore has a thicker optical cavity than green pixel 22-G and green pixel 22-G has a thicker optical cavity than blue pixel 22-B.

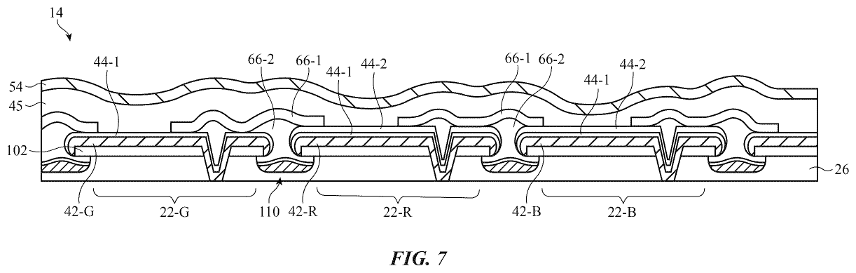

FIG. 7 shows an example of a two-cavity arrangement for display 14. As shown in FIG. 7, a first transparent conductive layer 44-1 is patterned to include a portion in red pixel 22-R, a portion in green pixel 22-G, and a portion in blue pixel 22-B. A second transparent conductive layer 44-2 is patterned to include a portion in red pixel 22-R, a portion in blue pixel 22-B, but no portion in green pixel 22-G. The green pixel 22-G has a transparent anode portion defined by layer 44-1. The blue pixel 22-B has a transparent anode portion defined by layers 44-1 and 44-2. The red pixel 22-R has a transparent anode portion defined by layers 44-1 and 44-2. The red and blue pixels therefore have optical cavities of a first thickness whereas the green pixel has an optical cavity with a second thickness that is less than the first thickness.

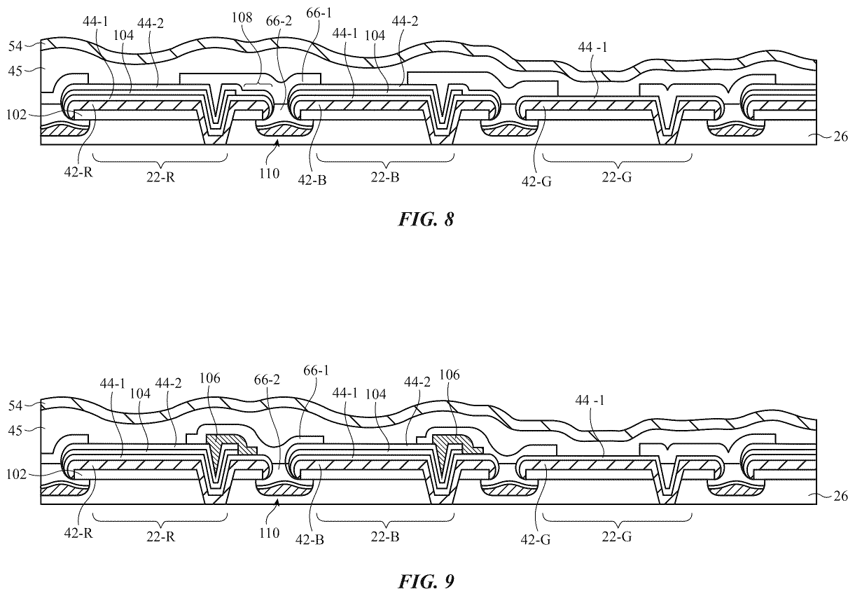

FIG. 8 shows an example of a two-cavity arrangement for display 14. As shown in FIG. 8, a first transparent conductive layer 44-1 is patterned to include a portion in red pixel 22-R, a portion in green pixel 22-G, and a portion in blue pixel 22-B. A second transparent conductive layer 44-2 is patterned to include a portion in red pixel 22-R, a portion in blue pixel 22-B, but no portion in green pixel 22-G. A dielectric spacer 104 is patterned to include a portion in red pixel 22-R, a portion in blue pixel 22-B, but no portion in green pixel 22-G. Dielectric spacer 104 is interposed between transparent conductive layers 44-1 and 44-2. Each dielectric spacer may be formed from a dielectric material such as silicon dioxide, silicon nitride, silicon oxynitride, titanium oxide, aluminum oxide, etc.

In FIG. 8, the green pixel 22-G has a transparent anode portion defined by layer 44-1. The blue pixel 22-B has a transparent anode portion defined by layers 44-1, 44-2, and 104. The red pixel 22-R has a transparent anode portion defined by layers 44-1, 44-2, and 104. The red and blue pixels therefore have optical cavities of a first thickness whereas the green pixel has an optical cavity with a second thickness that is less than the first thickness.

In FIG. 8, transparent conductive layers 44-1 and 44-2 within a given pixel may be electrically connected in a contact region 108. Outside of contact region 108, dielectric spacer 104 is interposed between layers 44-1 and 44-2. Inside contact region 108, layers 44-1 and 44-2 are in direct physical and electrical contact.

To improve the robustness of the physical and electrical contact between layers 44-1 and 44-2, a separate conductive layer may be included to electrically connect layers 44-1 and 44-2 in pixels 22-R and 22-B. FIG. 9 is a cross-sectional side view of a two-cavity arrangement for display 14 with a conductive layer that electrically connects layers 44-1 and 44-2. The display of FIG. 9 is similar to the display of FIG. 8 and duplicate components will not be describe herein for simplicity. As shown in FIG. 9, conductive contact 106 may be included in red and blue pixels 22-R and 22-B to electrically connect layers 44-1 and 44-2. Conductive contact 106 may sometimes be referred to as a bridge contact, metal bridge, etc. Each conductive contact 106 may be in direct physical and electrical contact with both transparent conductive layer 44-1 and transparent conductive layer 44-2. Conductive contacts 106 may be formed from molybdenum, titanium, or another desired conductive material. Conductive contacts 106 are outside the light-emitting aperture of the pixel and therefore may be opaque without mitigating overall display efficiency. Conductive contact 106 may have a transparency that is less than 30%, less than 20%, less than 10%, etc.

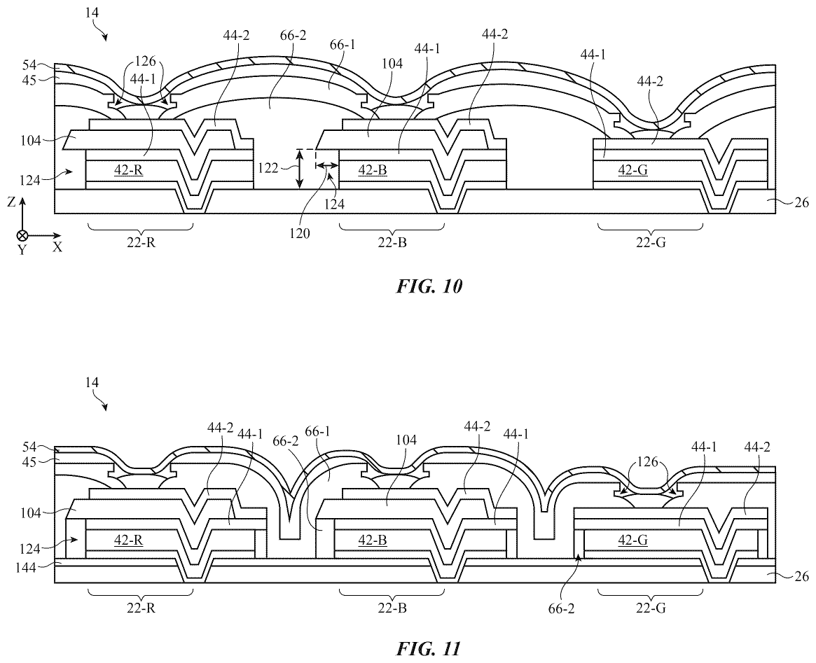

FIGS. 5-9 also show arrangements for one or more pixel definition layers. In the example of FIGS. 5-9, there are at least two pixel definition layers formed from different materials. Pixel definition layer 66-2 may fill the trenches 110 in substrate 26. Pixel definition layer 66-2 may be formed from polyimide or another desired material. An additional pixel definition layer 66-1 may be formed from a different material than pixel definition layer 66-2. Pixel definition layer 66-1 may define light-emitting apertures for each pixel within display 14. Pixel definition layer 66-1 may include an undercut that creates discontinuities in one or more OLED layers 45 as will be shown and discussed in greater detail in connection with FIGS. 10-16.

In FIGS. 5-7, pixel definition layer 66-2 overflows trenches 110. In other words, pixel definition layer 66-2 extends past an upper surface of overhang layer 102, reflective conductive layer 42, and transparent conductive layers 44 (e.g., in the positive Z-direction). In FIGS. 5-7, pixel definition layer 66-2 may have portions that are in direct contact with the upper surface of one or more transparent conductive layers 44. This example is merely illustrative. In another possible arrangement, shown in FIGS. 8 and 9, the pixel definition layer 66-2 may be contained within the trenches such that the pixel definition layer 66-2 does not extend past an upper surface of reflective conductive layer 42 or transparent conductive layers 44.

In arrangements where a single pixel includes multiple transparent conductive layers (e.g., in FIGS. 6-9), the transparent conductive layers may be formed from a single material or from two or more different materials. As one example, in FIG. 6, transparent conductive layers 44-1, 44-2, and 44-3 may all be formed from indium tin oxide (ITO). In FIG. 7, transparent conductive layer 44-1 may be formed from indium tin oxide whereas transparent conductive layer 44-2 may be formed from indium zinc oxide (IZO). In FIGS. 8 and 9, transparent conductive layers 44-1 and 44-2 may both be formed from indium tin oxide (ITO). There may optionally be a titanium oxide liner between two adjacent transparent conductive layers within a given pixel. For example, there may be a titanium oxide liner between ITO layer 44-1 and IZO layer 44-2 in FIG. 7.

In FIGS. 5-9, a discrete portion of reflective conductive layer 44 is formed in each trench 110. This example is merely illustrative and an additional etching step may be performed to remove any portions of reflective conductive layer 44 from trenches 110 if desired.

In FIGS. 5-9, substrate 26 (with trenches 110) and dielectric overhang layer 102 combine to define undercuts 114 that cause discontinuities in reflective anode portions 42. This example is merely illustrative. In general, any desired combination of insulating and/or conductive materials may be used to define undercuts that cause discontinuities in reflective anode portions 42.

The examples in FIGS. 5-9 of using trenches in substrate 26 to create discontinuities in reflective anode portions 42 is merely illustrative. Additional embodiments for display 14 with pixels having dielectric spacers are shown in FIGS. 10-12. FIG. 10 shows an example of a two-cavity arrangement for display 14. As shown in FIG. 10, a first transparent conductive layer 44-1 is patterned to include a portion in red pixel 22-R, a portion in green pixel 22-G, and a portion in blue pixel 22-B. A second transparent conductive layer 44-2 is patterned to include a portion in red pixel 22-R, a portion in green pixel 22-G, and a portion in blue pixel 22-B. A dielectric spacer 104 is patterned to include a portion in red pixel 22-R, a portion in blue pixel 22-B, but no portion in green pixel 22-G. Dielectric spacer 104 is interposed between transparent conductive layers 44-1 and 44-2 in pixels 22-R and 22-B. Each dielectric spacer may be formed from a dielectric material such as silicon dioxide, silicon nitride, silicon oxynitride, titanium oxide, aluminum oxide, etc.

As shown in FIG. 10, each dielectric spacer may be formed on and in direct contact with an upper surface of transparent conductive layer 44-1. Dielectric spacer 104 may extend past transparent conductive layer 44-1 in a direction parallel to the plane of display 14 (e.g., within the XY-plane of FIG. 10). As shown in FIG. 10, dielectric spacer 104 has an edge that is separated from the edge of transparent conductive layer 44-1 and reflective anode portion 42 by distance 120. This overhang region of dielectric spacer 104 defines an undercut 124. Distance 120 may be referred to as the width of undercut 124. Undercut 124 may have a height 122 defined by the separation between the lower surface of overhang layer 112 and the upper surface of substrate 26 between adjacent pixels.

The overhang of dielectric spacer 104 and corresponding undercut may improve the aperture ratio of the pixels by improving tolerance when depositing pixel definition layers 66-1 and/or 66-2. In FIG. 10, pixel definition layer 66-2 is formed between adjacent pixels and conforms to the sidewalls of reflective anode portions 42 and transparent anode portions 44. An additional pixel definition layer 66-1 is formed over pixel definition layer 66-2. Pixel definition layer 66-1 defines light-emitting apertures for the pixels. Pixel definition layer 66-2 may be formed from polyimide or another desired material. Additional pixel definition layer 66-1 may be formed from a different material than pixel definition layer 66-2.

FIG. 10 shows how pixel definition layer 66-1 may include one or more undercuts 126. The undercuts 126 may create discontinuities in one or more layers of OLED layers 45 to mitigate lateral leakage of current through the OLED layers. FIG. 10 shows how OLED layers 45 may have discontinuities caused by the undercuts, resulting in some discrete portions of the OLED layers positioned between the undercuts 126 (within the light-emitting aperture of the pixel) and some discrete portions of the OLED layers positioned over pixel definition layer 66-1. Although creating discontinuities in one or more OLED layers 45, undercuts 126 may not cause discontinuities in cathode 54.

In FIG. 10, the green pixel 22-G has a transparent anode portion defined by layers 44-1 and 44-2. The blue pixel 22-B has a transparent anode portion defined by layers 44-1, 44-2, and 104. The red pixel 22-R has a transparent anode portion defined by layers 44-1, 44-2, and 104. The red and blue pixels therefore have optical cavities of a first thickness whereas the green pixel has an optical cavity with a second thickness that is less than the first thickness.

In FIG. 10, pixel definition layer 66-2 is formed between substrate 26 and pixel definition layer 66-1 (which defines undercuts 126). This example is merely illustrative. In another possible arrangement, the position of these pixel definition layers may be flipped such that pixel definition layer 66-1 (which defines undercuts 126) is formed between substrate 26 and pixel definition layer 66-2. With this type of arrangement, pixel definition layer 66-1 (which defines undercuts 126) may also conform to the edges of the anode stacks. Forming pixel definition layer 66-2 above pixel definition layer 66-1 in this manner may increase the aperture ratio of the pixels. Pixel definition layer 66-2 may be positioned above pixel definition layer 66-1 in any of the displays described herein.

The example in FIG. 10 of pixel definition layer 66-2 filling the space between adjacent anodes (including undercut 124) is merely illustrative. In another possible arrangement, shown in FIG. 11, portions of pixel definition layer 66-2 are formed adjacent to the sidewalls of the pixel anode portions without completely filling the space between adjacent anode stacks. In red pixel 22-R, on the left side of the anode stack, pixel definition layer 66-2 conforms to the sidewalls of reflective anode portion 42-R and transparent conductive layer 44-1. Dielectric spacer 104 covers and is in direct contact with the upper surface of pixel definition layer 66-2 in this region. In red pixel 22-R, on the right side of the anode stack, pixel definition layer 66-2 conforms to the sidewalls of reflective anode portion 42-R. Transparent conductive layer 44-1 covers and is in direct contact with the upper surface of pixel definition layer 66-2 in this region. In blue pixel 22-B, on the left side of the anode stack, pixel definition layer 66-2 conforms to the sidewalls of reflective anode portion 42-B and transparent conductive layer 44-1. Dielectric spacer 104 covers and is in direct contact with the upper surface of pixel definition layer 66-2 in this region. In blue pixel 22-B, on the right side of the anode stack, pixel definition layer 66-2 conforms to the sidewalls of reflective anode portion 42-B. Transparent conductive layer 44-1 covers and is in direct contact with the upper surface of pixel definition layer 66-2 in this region. In green pixel 22-G, on the left side of the anode stack, pixel definition layer 66-2 conforms to the sidewall of reflective anode portion 42-G. Transparent conductive layer 44-1 covers and is in direct contact with the upper surface of pixel definition layer 66-2 in this region. In green pixel 22-G, on the right side of the anode stack, pixel definition layer 66-2 conforms to the sidewall of reflective anode portion 42-R. Transparent conductive layer 44-1 covers and is in direct contact with the upper surface of pixel definition layer 66-2 in this region. The portions of pixel definition layer 66-2 under the overhang portions may be referred to as polyimide plugs. Pixel definition layer 66-1 may be interposed between the polyimide plugs of adjacent anode stacks. For example, pixel definition layer 66-1 is interposed between the polyimide plug 66-2 on the right side of pixel 22-R and the polyimide plug 66-2 on the left side of pixel 22-B.

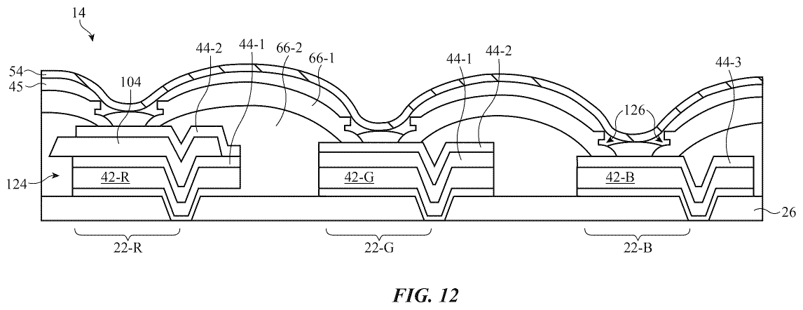

FIG. 12 shows an example of a three-cavity arrangement for display 14. As shown in FIG. 12, a first transparent conductive layer 44-1 is patterned to include a portion in red pixel 22-R a portion in green pixel 22-G, but no portion in blue pixel 22-B. A second transparent conductive layer 44-2 is patterned to include a portion in red pixel 22-R, a portion in green pixel 22-G, but no portion in blue pixel 22-B. A third transparent conductive layer 44-3 is patterned to include a portion in blue pixel 22-B but no portions in red pixel 22-R or green pixel 22-G. A dielectric spacer 104 is patterned to include a portion in red pixel 22-R but no portions in blue pixel 22-B or green pixel 22-G. Dielectric spacer 104 is interposed between transparent conductive layers 44-1 and 44-2. Dielectric spacer 104 may be formed from a dielectric material such as silicon dioxide, silicon nitride, silicon oxynitride, titanium oxide, aluminum oxide, etc. The pixel definition layer arrangement in FIG. 12 is the same as in FIG. 10.

In FIG. 12, the blue pixel 22-B has a transparent anode portion defined by layer 44-3. The green pixel 22-G has a transparent anode portion defined by layers 44-1 and 44-2. The red pixel 22-R has a transparent anode portion defined by layers 44-1, 44-2, and 104. The red pixel 22-R therefore has a thicker optical cavity than green pixel 22-G and green pixel 22-G has a thicker optical cavity than blue pixel 22-B.

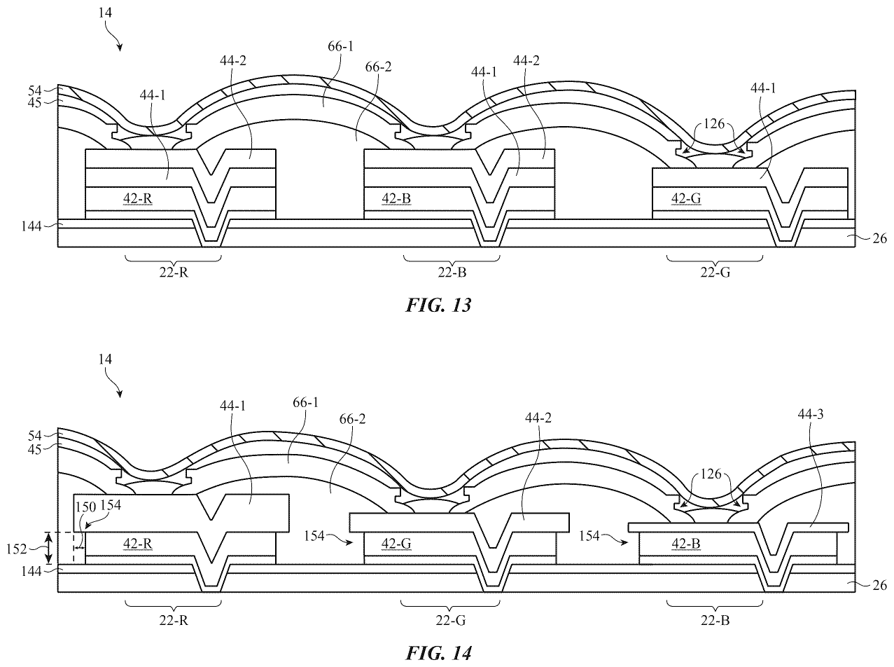

FIG. 13 shows an example of a two-cavity arrangement for display 14. As shown in FIG. 13, a first transparent conductive layer 44-1 is patterned to include a portion in red pixel 22-R, a portion in green pixel 22-G, and a portion in blue pixel 22-B. A second transparent conductive layer 44-2 is patterned to include a portion in red pixel 22-R, a portion in blue pixel 22-B, but no portion in green pixel 22-G. In FIG. 13, the blue pixel 22-B has a transparent anode portion defined by layers 44-1 and 42. The green pixel 22-G has a transparent anode portion defined by layer 44-1. The red pixel 22-R has a transparent anode portion defined by layers 44-1 and 44-2. The red and blue pixels therefore have optical cavities of a first thickness whereas the green pixel has an optical cavity with a second thickness that is less than the first thickness.

FIG. 14 shows an example of a three-cavity arrangement for display 14. As shown in FIG. 14, a first transparent conductive layer 44-1 is patterned to include a portion in red pixel 22-R, a second transparent conductive layer 44-2 is patterned to include a portion in green pixel 22-G, and a third transparent conductive layer 44-3 is patterned to include a portion in blue pixel 22-B. Layer 44-1 is thicker than layer 44-2 and layer 44-2 is thicker than layer 44-3. Accordingly, the blue pixel 22-B has a transparent anode portion defined by layer 44-3. The green pixel 22-G has a transparent anode portion defined by layer 44-2. The red pixel 22-R has a transparent anode portion defined by layer 44-1. The red pixel 22-R has a thicker optical cavity than green pixel 22-G and green pixel 22-G has a thicker optical cavity than blue pixel 22-B.

As shown in FIG. 14, each transparent conductive layer 44 has an edge that is separated from the edge of a respective reflective anode portion 42 by distance 150. This overhang region of transparent conductive layer 44 defines an undercut 154. Distance 150 may be referred to as the width of undercut 154. Undercut 154 may have a height 152 defined by the separation between the lower surface of transparent conductive layer 44 and the upper surface of passivation layer 144 between adjacent pixels. The overhang of transparent conductive layer 44 and corresponding undercut may improve the aperture ratio of the pixels by improving tolerance when depositing pixel definition layers 66-1 and/or 66-2.

In FIGS. 13 and 14, the pixel definition layers have the same arrangement as in FIGS. 10 and 12.

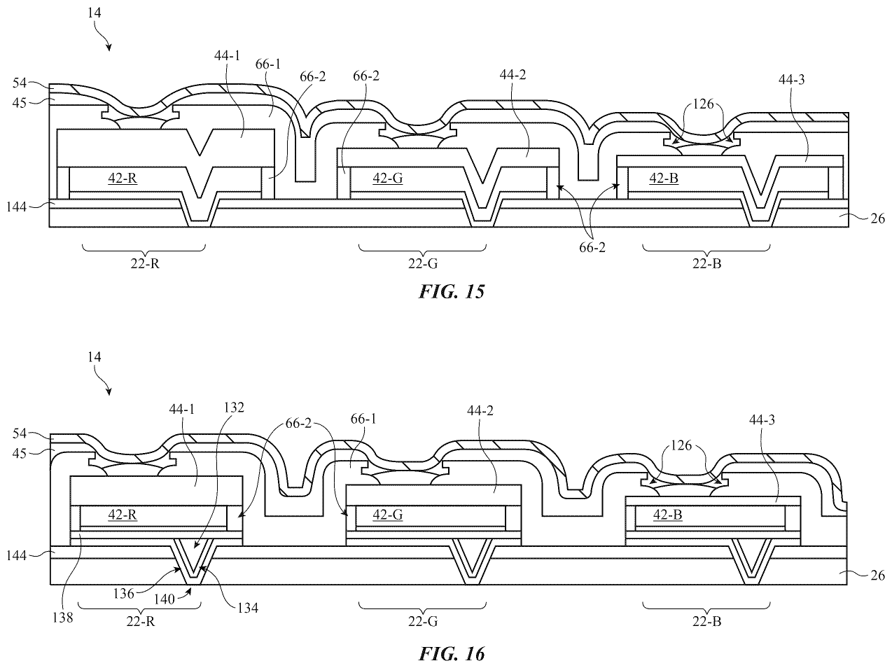

FIG. 15 shows an example of a three-cavity arrangement for display 14 similar to the arrangement of FIG. 14. However, display 14 in FIG. 15 has the pixel definition layer arrangement of FIG. 11. As shown in FIG. 15, in red pixel 22-R, on the left side of the anode stack, pixel definition layer 66-2 conforms to the sidewalls of reflective anode portion 42-R. Transparent conductive layer 44-1 covers and is in direct contact with the upper surface of pixel definition layer 66-2 in this region. In red pixel 22-R, on the right side of the anode stack, pixel definition layer 66-2 conforms to the sidewalls of reflective anode portion 42-R. Transparent conductive layer 44-1 covers and is in direct contact with the upper surface of pixel definition layer 66-2 in this region. In green pixel 22-G, on the left side of the anode stack, pixel definition layer 66-2 conforms to the sidewalls of reflective anode portion 42-G. Transparent conductive layer 44-2 covers and is in direct contact with the upper surface of pixel definition layer 66-2 in this region. In green pixel 22-G, on the right side of the anode stack, pixel definition layer 66-2 conforms to the sidewalls of reflective anode portion 42-G. Transparent conductive layer 44-2 covers and is in direct contact with the upper surface of pixel definition layer 66-2 in this region. In blue pixel 22-B, on the left side of the anode stack, pixel definition layer 66-2 conforms to the sidewall of reflective anode portion 42-B. Transparent conductive layer 44-3 covers and is in direct contact with the upper surface of pixel definition layer 66-2 in this region. In blue pixel 22-B, on the right side of the anode stack, pixel definition layer 66-2 conforms to the sidewall of reflective anode portion 42-B. Transparent conductive layer 44-3 covers and is in direct contact with the upper surface of pixel definition layer 66-2 in this region. Pixel definition layer 66-1 may be interposed between the polyimide plugs of adjacent anode stacks. For example, pixel definition layer 66-1 is interposed between the polyimide plug 66-2 on the right side of pixel 22-R and the polyimide plug 66-2 on the left side of pixel 22-G.

FIG. 16 is a cross-sectional side view of an illustrative display with a three-cavity arrangement. The three-cavity arrangement of FIG. 16 is similar to the arrangement of FIG. 15 and duplicate components will not be described again for simplicity. In FIG. 16, each pixel includes via planarization for a via that electrically connects the anode to a control signal contact. As shown in FIG. 16, each pixel includes a first conductive layer that is formed in a via 140. A second conductive layer 138 is formed over the first conductive layer. Outside of via 140, conductive layers 136 and 138 are in direct contact with one another. Conductive layer 138 may be interposed between conductive layer 136 and additional conductive components of the anode stack. Within via 140, planarization layer 132 is interposed between conductive layers 136 and 138. Planarization layer 132 may be formed from the same material as pixel definition layer 66-2 if desired. As one example, both planarization layer 132 and pixel definition layer 66-2 may both be formed from polyimide. A dielectric liner 134 formed from silicon nitride or another desired material may be interposed between planarization layer 132 and conductive layer 136. The liner 134 may improve etching end point detection during the manufacturing process. Conductive layers 136 and 138 may be formed from titanium, molybdenum, or another desired conductive material. Conductive layers 136 and 138 may have a transparency that is less than 30%, less than 20%, less than 10%, etc. Conductive layers 136 and 138 may be formed from a transparent conductive material (e.g., indium tin oxide, indium zinc oxide, etc.) and may have a transparency that is greater than 60%, greater than 70%, greater than 80%, greater than 90%, greater than 95%, etc.

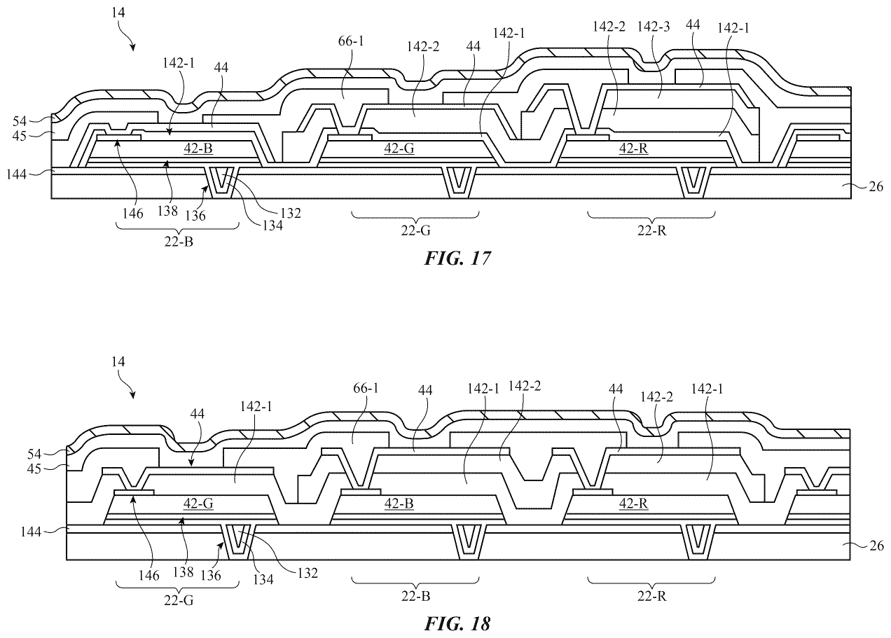

FIG. 17 is a cross-sectional side view of an illustrative display with a three-cavity arrangement. Each pixel in FIG. 17 has a planarized via formed from conductive layers 136 and 138, planarization layer 132, and liner 134 (similar to as shown and described in connection with FIG. 16). Each anode stack also includes a conductive layer 146 that is formed on a respective reflective anode portion 42. Reflective anode portion 42 is interposed between conductive layers 146 and 138. Each conductive layer 146 may be formed from titanium, molybdenum, or another desired conductive material. Conductive layer 146 may have a transparency that is less than 30%, less than 20%, less than 10%, etc. Conductive layer 146 may be formed from the same material as conductive layers 136 and 138 or a different material than conductive layers 136 and 138.

In FIG. 17, blue pixel 22-B has a transparent conductive layer 44 formed over a dielectric spacer 142-1. Dielectric spacer 142-1 is interposed between reflective anode portion 42-B and transparent conductive layer 44. Green pixel 22-G has a transparent conductive layer 44 formed over dielectric spacers 142-1 and 142-2. Dielectric spacers 142-1 and 142-2 are interposed between reflective anode portion 42-G and transparent conductive layer 44. Red pixel 22-R has a transparent conductive layer 44 formed over dielectric spacers 142-1, 142-2, and 142-3. Dielectric spacers 142-1, 142-2, and 142-3 are interposed between reflective anode portion 42-R and transparent conductive layer 44. Transparent conductive layer 44 therefore has a uniform thickness in pixels 22-B, 22-R, and 22-G. Dielectric spacer 142-1 has a uniform thickness in pixels 22-B, 22-G, and 22-R. Dielectric spacer 142-2 has a uniform thickness in pixels 22-G and 22-R. Dielectric spacers 142-1, 142-2, and 142-3 may be formed from a dielectric material such as silicon dioxide, silicon nitride, silicon oxynitride, titanium oxide, aluminum oxide, etc.

FIG. 17 further shows how a passivation layer 144 may be formed on an upper surface of substrate 26. Passivation layer 144 may protect substrate 26 during one or more etching processes (e.g., during a dry etching process for the pixel anodes). Passivation layer 144 may optionally be formed from the same material as liner 134 if desired. As one example, passivation layer 144 and liner 134 may both be formed from silicon nitride. A passivation layer 144 may be incorporated on the upper surface of substrate 26 for any of the embodiments herein (see optional passivation layer 144 in FIGS. 11 and 13-16).

In FIG. 17, the red pixel 22-R has a thicker optical cavity than green pixel 22-G and green pixel 22-G has a thicker optical cavity than blue pixel 22-B.

FIG. 18 is a cross-sectional side view of an illustrative display with a two-cavity arrangement. Each pixel in FIG. 18 has a planarized via formed from conductive layers 136 and 138, planarization layer 132, and liner 134 (similar to as shown and described in connection with FIGS. 17). In FIG. 18, green pixel 22-G has a transparent conductive layer 44 formed over a dielectric spacer 142-1. Dielectric spacer 142-1 is interposed between reflective anode portion 42-G and transparent conductive layer 44. Blue pixel 22-B has a transparent conductive layer 44 formed over dielectric spacers 142-1 and 142-2. Dielectric spacers 142-1 and 142-2 are interposed between reflective anode portion 42-B and transparent conductive layer 44. Red pixel 22-R has a transparent conductive layer 44 formed over dielectric spacers 142-1 and 142-2. Dielectric spacers 142-1 and 142-2 are interposed between reflective anode portion 42-R and transparent conductive layer 44. Transparent conductive layer 44 therefore has a uniform thickness in pixels 22-B, 22-R, and 22-G. Dielectric spacer 142-1 has a uniform thickness in pixels 22-B, 22-G, and 22-R. Dielectric spacer 142-2 has a uniform thickness in pixels 22-B and 22-R. Dielectric spacers 142-1 and 142-2 may be formed from a dielectric material such as silicon dioxide, silicon nitride, silicon oxynitride, titanium oxide, aluminum oxide, etc.

The red and blue pixels of FIG. 18 have optical cavities of a first thickness whereas the green pixel has an optical cavity with a second thickness that is less than the first thickness.

In any of the embodiments herein, the reflective anode portions 42 may comprise aluminum, silver, and/or another desired material. As examples, the reflective anode portions 42 in FIGS. 5-16 may comprise silver whereas the reflective anode portions 42 in FIGS. 17-18 may comprise aluminum.

Herein, each transparent layer in the anode stack (e.g., transparent conductive layers, dielectric spacers, etc.) may have a transparency that is greater than 60%, greater than 70%, greater than 80%, greater than 90%, greater than 95%, etc. Each reflective layer in the anode stack (e.g., reflective conductive layers) may have a reflectivity that is greater than 60%, greater than 70%, greater than 80%, greater than 90%, greater than 95%, etc.

The foregoing is merely illustrative and various modifications can be made by those skilled in the art without departing from the scope and spirit of the described embodiments. The foregoing embodiments may be implemented individually or in any combination.

What is claimed is:

1. A display comprising a plurality of pixels, the display comprising:
a substrate;
a reflective conductive layer with a first plurality of discrete portions on the substrate;
a first transparent conductive layer with a second plurality of discrete portions;
a second transparent conductive layer with a third plurality of discrete portions; and
a dielectric spacer layer with a fourth plurality of discrete portions,
wherein each one of a first subset of the plurality of pixels has a respective anode stack that comprises a respective one of the first plurality of discrete portions, a respective one of the second plurality of discrete portions, a respective one of the third plurality of discrete portions, and a respective one of the fourth plurality of discrete portions that is interposed between the respective one of the second plurality of discrete portions and the respective one of the third plurality of discrete portions.

2. The display defined in claim 1, wherein, in the first subset of the plurality of pixels, the respective one of the fourth plurality of discrete portions has an overhang portion that extends past an edge of the respective one of the second plurality of discrete portions.

3. The display defined in claim 2, wherein, in the first subset of the plurality of pixels, the overhang portion extends past an edge of the respective one of the first plurality of discrete portions.

4. The display defined in claim 1, wherein each one of a second subset of the plurality of pixels has a respective anode stack that comprises an additional respective one of the first plurality of discrete portions, an additional respective one of the second plurality of discrete portions, and an additional respective one of the third plurality of discrete portions.

5. The display defined in claim 4, wherein, in the second subset of the plurality of pixels, the additional respective one of the second plurality of discrete portions is adjacent to the additional respective one of the third plurality of discrete portions without any intervening portion of the dielectric spacer layer.

6. The display defined in claim 4, wherein each one of the first subset of the plurality of pixels has a first cavity thickness and wherein each one of the second subset of the plurality of pixels has a second cavity thickness that is less than the first cavity thickness.

7. The display defined in claim 4, wherein each one of a third subset of the plurality of pixels has a respective anode stack that comprises a second additional respective one of the first plurality of discrete portions and a second additional respective one of the second plurality of discrete portions, wherein each one of the first subset of the plurality of pixels has a first cavity thickness, wherein each one of the second subset of the plurality of pixels has a second cavity thickness that is less than the first cavity thickness, and wherein each one of the third subset of the plurality of pixels has a third cavity thickness that is less than the second cavity thickness.

8. The display defined in claim 4, further comprising:
organic light-emitting diode layers in both the first and second subsets of the plurality of pixels; and
a cathode that overlaps the organic light-emitting diode layers.

9. The display defined in claim 1, further comprising:
a first pixel definition layer that is interposed between adjacent pixels of the plurality of pixels; and
a second pixel definition layer that overlaps the first pixel definition layer and that defines light-emitting apertures for the plurality of pixels.

10. The display defined in claim 9, wherein the first pixel definition layer comprises polyimide.

11. The display defined in claim 9, wherein the first pixel definition layer has an upper surface that extends above upper surfaces of the first and second transparent conductive layers.

12. The display defined in claim 9, wherein the first pixel definition layer has portions that fill undercuts in the anode stacks of the first subset of the plurality of pixels.

13. The display defined in claim 9, wherein the second pixel definition layer comprises at least one undercut.

14. A display comprising a plurality of pixels, the display comprising:
a substrate having a plurality of trenches;
a layer that overlaps the substrate, wherein the layer comprises a plurality of overhang portions that overlap the plurality of trenches and define a plurality of undercuts;
a reflective conductive layer with a first plurality of discrete portions on the layer and a second plurality of discrete portions in the plurality of trenches; and
a transparent conductive layer with a third plurality of discrete portions on the reflective conductive layer, wherein each one of the plurality of pixels comprises an anode stack that includes a respective one of the first plurality of discrete portions and a respective one of the third plurality of discrete portions.

15. The display defined in claim 14, further comprising:
a dielectric spacer layer with a fourth plurality of discrete portions on the transparent conductive layer; and
an additional transparent conductive layer with a fifth plurality of discrete portions on the dielectric spacer layer.

16. The display defined in claim 15, wherein the anode stack for a first subset of the plurality of pixels does not include any of the fourth plurality of discrete portions and wherein the anode stack for a second subset of the plurality of pixels includes a respective one of the fourth plurality of discrete portions and a respective one of the fifth plurality of discrete portions.

17. The display defined in claim 16, further comprising:
organic light-emitting diode layers in both the first and second subsets of the pixels; and
a cathode that overlaps the organic light-emitting diode layers.

18. The display defined in claim 17, wherein the first subset of the plurality of pixels has a first cavity thickness between the cathode and the reflective conductive layer, wherein the second subset of the plurality of pixels has a second cavity thickness between the cathode and the reflective conductive layer, and wherein the second cavity thickness is greater than the first cavity thickness.

19. A display comprising a plurality of pixels, wherein a pixel in the plurality of pixels comprises:
a reflective anode portion;
a transparent anode portion that is electrically connected to the reflective anode portion;
organic light-emitting diode layers that overlap the transparent anode portion, wherein the transparent anode portion is interposed between the reflective anode portion and the organic light-emitting diode layers; and
a cathode that overlaps the organic light-emitting diode layers, wherein the transparent anode portion extends past an edge of the reflective anode portion to create an undercut under the transparent anode portion.

20. The display defined in claim 19, further comprising:
a first pixel definition layer that is formed within the undercut; and
a second pixel definition layer that defines a light-emitting aperture for the pixel.

21. The display defined in claim 19, further comprising:
a substrate, wherein the reflective anode portion is formed on the substrate; and
a via through the substrate that is electrically connected to the reflective anode portion, wherein the via comprises one or more conductive layers and a planarization layer.
